(19) United States
(12) Patent Application Publication
(10) Pub. No.: US 2008/0298412 A1
(43) Pub. Date: Dec. 4, 2008

(54) SEMICONDUCTOR LASER DEVICE AND MANUFACTURING METHOD THEREOF

(76) Inventor: ATSUSHI NAKAMURA, Komoro (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/859,029

(22) Filed: Nov. 28, 2007

(30) Foreign Application Priority Data
Sep. 21, 2006 (JP) JP2006-255167

(51) Int. Cl. H01S 5/30; H01L 21/02

(52) U.S. Cl. 372/45.011; 438/39; 257/E21.002

(57) ABSTRACT

A semiconductor laser device having a MQW structure composed of an active layer, a p-type second clad layer, and a p-type first clad layer sequentially stacked on an n-type clad layer provided on an n-type GaAs substrate is provided. In the semiconductor laser device, the n-type clad layer and the p-type first clad layer are lattice-matched to the GaAs substrate. A negative strain layer is provided in an intermediate layer of the first clad layer, in which a positive strain layer is provided on both surfaces or one surface of the negative strain layer.

### CROSS-REFERENCE TO RELATED APPLICATION

The present application claims priority from Japanese Patent Application No. JP 2006-255167 filed on Sep. 21, 2006, the content of which is hereby incorporated by reference into this application.

### TECHNICAL FIELD OF THE INVENTION

The present invention relates to a semiconductor laser device and a method of manufacturing the same. For example, the present invention relates to a technique effectively applied to improve high-temperature characteristics.

### BACKGROUND OF THE INVENTION

Lasers for recording information use AlGaInP-based materials. A semiconductor laser device (laser diode: LD) composed of the AlGaInP-based material has a structure having, for example, an n-type clad layer composed of an n-type AlGaInP layer, an active layer, and a p-type clad layer composed of a p-type AlGaInP layer on a main surface of an n-type GaAs substrate. It is known that temperature characteristics are improved in such a semiconductor laser device when a layer in which an energy bandgap is large is formed for at least one of the clad layers.

Meanwhile, a semiconductor laser device in which the lattice constant of an active layer serving as a light emitting part is intentionally shifted from lattice matching is known. Specifically, a semiconductor laser device in which, in AlGaInP forming a clad layer, a tensile stress is applied to the crystal for a composition having a partially large lattice constant so as to increase its bandgap has been proposed (e.g., Japanese Patent Application Laid-Open Publication No. 5-41560 (Patent Document 1)). The oscillation wavelength of the semiconductor laser device disclosed in Patent Document 1 is 0.5 μm band.

Also, a semiconductor laser device in which negative strain is introduced to a clad layer in order to increase the bandgap of the clad layer has been proposed (e.g., Japanese Patent Application Laid-Open Publication No. 7-235733 (Patent Document 2)).

It is known that crystal defects are generated when a numerical value obtained by multiplying the magnitude of strain by the thickness of a crystal film exceeds a critical value (critical strain) in the case where desired strain is formed by combining crystals having different lattice constants (for example, J. W. Matthews and A. E. Blakeslee: Defects in Epitaxial Multi-layers, J. Cryst. Growth 27 (1974), pp. 118-125 (Non-patent Document 1)).

### SUMMARY OF THE INVENTION

In the AlGaInP-based semiconductor laser device, its energy bandgap corresponding to an oscillation wavelength is large. Therefore, an enough bandgap difference with the clad layer cannot be reserved. As a result, characteristics (I-L characteristics) are deteriorated due to overflow of electrons under a high temperature of 50° C. or more. Introducing negative strain to the clad layer in order to increase the energy bandgap difference is known as described above.

The inventor of the present invention has also studied about the semiconductor laser device in which negative strain is introduced to the clad layer in order to increase the energy bandgap difference and has found out that crystallinity of the clad layer is deteriorated and thus good light emitting property is difficult to obtain when the tensile strain is introduced to the clad layer.

FIG. 18 is a schematic cross sectional view showing a part of a semiconductor laser device 59 having a wavelength of 630 nm band which has been studied prior to the present invention.

As shown in FIG. 18, the semiconductor laser device 59 is manufactured based on a semiconductor substrate 60 which has a thickness of about 100 μm and is composed of n-type GaAs. On a main surface of the semiconductor substrate 60, a buffer layer 61, which has a thickness of 1000 nm and is composed of n-type AlGaInP, is provided. On the buffer layer 61, an n-type clad layer 62, an active layer 63, a p-type second clad layer 64, a p-type first clad layer 65, and a contact layer 66 are provided.

The n-type clad layer 62 is composed of n-type (Al_{0.60}Ga_{0.40})_{0.53}In_{0.47}P having a thickness of 50 nm. The active layer 63 is formed by a multi-quantum well structure (MQW), in which barrier layers each of which having a thickness of 6 nm and composed of (Al_{0.60}Ga_{0.40})_{0.53}In_{0.47}P and well layers each of which having a thickness of 12 nm and composed of In_{0.38}Ga_{0.62}P are alternately stacked. The active layer 63 comprises two well layers and three barrier layers. The p-type second clad layer 64 is composed of p-type (Al_{0.60}Ga_{0.40})_{0.53}In_{0.47}P having a thickness of 50 nm. The p-type first clad layer 65 is composed of p-type (Al_{0.70}Ga_{0.30})_{0.53}In_{0.47}P having a thickness of 2.0 μm. The contact layer 66 is composed of p-type GaAs having a thickness of 0.2 μm.

On the main surface side of the semiconductor substrate 60, two grooves 70 are provided in parallel with each other. The grooves 70 are provided from a surface of the contact layer 66 to an intermediate depth that is in the p-type first clad layer 65. The part sandwiched between the two grooves 70 is a mesa 71. An insulating film 73 covering side surfaces of the mesa 71, the grooves 70, and an upper surface part (field part 72) of the contact layer 66, which is outside the grooves 70, is provided. More specifically, the semiconductor laser device 59 has a structure in which a second surface side of the semiconductor substrate 60 is covered by the insulating film 73, and an upper surface of the mesa 71, i.e., the contact layer 66 is exposed. On the exposed contact layer 66, an anode electrode (p-type electrode) 74 is stacked. The p-type electrode 74 is extended to a part above the field part 72 over the grooves 70. Furthermore, a cathode electrode (n-type electrode) 75 is stacked on a back surface side, which is the opposite surface of the main surface of the semiconductor substrate 60.

In such semiconductor laser device 59, when a predetermined voltage is applied between the p-type electrode 74 and the n-type electrode 75, which are a pair of electrodes, the active layer 63 part corresponding to the mesa 71 serves as a resonator and emits laser light from an end face of the resonator.

FIG. 19 is a band diagram of the semiconductor laser device 59. As shown in FIG. 19, in a well layer between barrier layers, electrons are confined in the conduction band, and holes are confined in the valence band. The energy bandgap of the well layer is an energy bandgap corresponding to an emission wavelength. When negative strain is formed in the p-type first clad layer 65 [p-AlGaInP (1)], as shown by dotted lines, the energy bandgap of the negative strain clad layer becomes larger than the energy bandgap of the lattice-matched clad in which negative strain is not formed.

Consequently, the confinement effect of electrons into the active layer 63 by the p-type first clad layer 65 is increased. Thus, an oscillation threshold current is reduced and temperature characteristics are improved as well.

In a conventional method of introducing negative strain to the clad layer, negative strain is introduced to the entirety of the clad layer. When a semiconductor laser device is manufactured by the conventional method, strain is introduced into the clad layer having a thickness of 2.0 μm as shown in FIG. 19. In this structure, crystal defects are generated due to the numerical value obtained by multiplying the thickness of the crystal film in which the negative strain is formed by the magnitude of the strain exceeds the critical strain, and thus the I-L characteristics and reliability of the semiconductor laser device are deteriorated.

An object of the present invention is to provide a semiconductor laser device having a good confinement effect of electrons into an active layer and a method of manufacturing thereof.

Another object of the present invention is to provide a semiconductor laser device capable of achieving a reduction of an oscillation threshold current and a method of manufacturing thereof.

Still another object of the present invention is to provide a semiconductor laser device having good temperature characteristics and a method of manufacturing thereof.

The above and other objects and novel characteristics of the present invention will be apparent from the description of this specification and the accompanying drawings.

The typical ones of the inventions disclosed in this application will be briefly described as follows.

(1) A semiconductor laser device includes:

a semiconductor substrate of a first conductive type (n type);

a buffer layer of the first conductive type formed on a main surface of the semiconductor substrate;

a clad layer of the first conductive type formed on an upper surface of the buffer layer;

an active layer formed on an upper surface of the clad layer;

a second clad layer of a second conductive type (p type) formed on an upper surface of the active layer;

a first clad layer of the second conductive type formed on an upper surface of the second clad layer;

a contact layer of the second conductive type formed on an upper surface of the first clad layer;

a second electrode which is stacked on the contact layer and provided so as to correspond to an end to another end of a narrow long resonator formed of: the clad layer of the first conductive type; the active layer; and the second clad layer and the first clad layer, and injects a current to the active layer part of the resonator; and a first electrode stacked on a back surface which is an opposite surface of the main surface of the semiconductor substrate, in which the clad layer of the first conductive type and the first clad layer are arranged to be lattice-matched to the semiconductor substrate;

a negative strain layer is provided in an intermediate layer of the first clad layer; and

a positive strain layer is provided on one or both surfaces of the negative strain layer.

The semiconductor laser device includes: two grooves provided from a surface of the contact layer so as to reach an intermediate depth of the first clad layer; a mesa formed between the two grooves and composed of the first clad layer and the contact layer; and an insulating film covering the grooves and the contact layer except for an upper surface of the mesa, in which the second electrode is electrically connected to the upper surface of the mesa, and a lower part of the mesa constitutes the resonator.

In the semiconductor device, the semiconductor substrate is composed of GaAs, and the clad layer of the first conductive type is composed of (Al_{0.60}Ga_{0.40})_{0.53}In_{0.47}P having a thickness of 50 nm. The active layer has a multi-quantum well structure in which a barrier layer composed of (Al_{0.60}Ga_{0.40})_{0.53}In_{0.47}P having a thickness of 6 nm and a well layer composed of In_{0.38}Ga_{0.62}P having a thickness of 12 nm are alternately stacked (three barrier layers and two well layers). The second clad layer is composed of (Al_{0.60}Ga_{0.40})_{0.53}In_{0.47}P having a thickness of 50 nm, the first clad layer is composed of (Al_{0.70}Ga_{0.30})_{0.53}In_{0.47}P having a thickness of 2.0 μm, and the contact layer is composed of GaAs having a thickness of 0.2 μm. The negative strain layer is formed by selecting a predetermined amount as a component amount of In in the intermediate layer of (Al_{0.70}Ga_{0.30})_{0.53}In_{0.47}P constituting the first clad layer. The positive strain layer is formed by selecting a predetermined amount as a component amount of In (Indium) in a region having a predetermined thickness in one or both surfaces of the intermediate layer of (Al_{0.70}Ga_{0.30})_{0.53}In_{0.47}P constituting the first clad layer.

In the semiconductor laser device, the negative strain layer has a strain of −0.5 to −1.5% and a thickness of 5 to 30 nm, and the positive strain layer has strain of +0.5 to +1.5% and a thickness of 5 to 30 nm.

A method of manufacturing such a semiconductor laser device includes:

(a) a step of preparing a semiconductor substrate of a first conductive type;

(b) a step of sequentially forming and stacking: a clad layer of the first conductive type; an active layer; a second clad layer of a second conductive type; a first clad layer of the second conductive type; and a contact layer of the second conductive type on a main surface of the semiconductor substrate;

(c) a step of forming a plurality of pairs of grooves reaching an intermediate depth of the first clad layer from a surface of the contact layer at a predetermined interval so that a plurality of projecting mesas each of which sandwiched between the pair of grooves above the active layer are formed, and forming a resonator below the mesa;

(d) a step of removing an upper surface of the mesa and forming an insulating film covering an upper surface side of the semiconductor substrate;

(e) a step of forming a second electrode selectively formed on the insulating film, a part thereof is stacked on the mesa;

(f) a step of forming a first electrode on a back surface which is an opposite surface of the main surface of the semiconductor substrate; and

(g) a step of dividing the semiconductor substrate and the layers thereon from a part between the mesa and mesa and cleaving the substrate and the layers in a direction orthogonal to the mesa at a predetermined interval so as to form a plurality of rectangular semiconductor laser devices,

in which, in the step (b),

the clad layer of the first conductive type and the first clad layer are formed so as to be lattice-matched to the semiconductor substrate,

a negative strain layer is provided in an intermediate layer of the first clad layer, and

a positive strain layer is provided on one or both surfaces of the negative strain layer.

In the step (a), a GaAs substrate is prepared as the semiconductor substrate; and,

in the step (b), the clad layer of the first conductive type having a thickness of 50 nm is formed of (Al_{0.60}Ga_{0.40})_{0.53}In_{0.47}P; the active layer is formed to have a multi-quantum well structure in which a barrier layer composed of (Al_{0.60}Ga_{0.40})_{0.53}In_{0.47}p having a thickness of 6 nm and a well layer composed of In_{0.38}Ga_{0.62}P having a thickness of 12 nm are alternately stacked (three barrier layers and two well layers); the second clad layer is formed of (Al_{0.60}Ga_{0.40})_{0.53}In_{0.47}P having a thickness of 50 nm; the first clad layer is formed of (Al_{0.70}Ga_{0.30})_{0.53}In_{0.47}P having a thickness of 2.0 μm; and the contact layer is formed of GaAs having a thickness of 0.2 μm. The negative strain layer is formed by selecting a predetermined amount as a component amount of In in the intermediate layer of (Al_{0.70}Ga_{0.30})_{0.53}In_{0.47}P composing the first clad layer. And the positive strain layer is formed by selecting a predetermined amount as a component amount of In in a region having a predetermined thickness in one or both surfaces of the intermediate layer of (Al_{0.70}Ga_{0.30})_{0.53}In_{0.47}P composing the first clad layer.

In the step (b), the negative strain layer having strain of −0.5 to −1.5% and a thickness of 5 to 30 nm is formed, and the positive strain layer having strain of +0.5 to +1.5% and a thickness of 5 to 30 nm is formed.

(2) In the configuration of (1) described above, a plurality of the negative strain layers and positive strain layers are alternately and periodically formed in the intermediate layer of the first clad layer of the second conductive type.

The semiconductor laser device as the above has, in the step (b) in the manufacturing method of a semiconductor laser device of the above (1), a plurality of the negative strain layers and the positive strain layers which are alternately and periodically formed.

The effects obtained by typical aspects of the present invention will be briefly described below.

According to the means of above described (1), (a) the negative strain layer is provided in the intermediate layer of the p-type first clad layer ((Al_{0.70}Ga_{0.30})_{0.53}In_{0.47}P), and the positive strain layer is provided on one or both surfaces thereof. The negative strain layer has a strain of −0.5 to −1.5% and a thickness of 5 to 30 nm. Further, the positive strain layer has a strain of +0.5 to +1.5% and a thickness of 5 to 30 nm.

The energy bandgap of the p-type first clad layer has a strain of ±0% since lattice matching is made between the p-type first clad layer and the GaAs substrate. On the other hand, the part in which the negative strain layer is formed has a strain of −0.5 to −1.5%, and the positive strain layers provided in both surface sides of the negative strain layer have a strain of +0.5 to +1.5%. Therefore, the energy bandgap is increased, overflow of electrons in the active layer becomes difficult, the characteristics (I-L characteristics) are improved, and the temperature characteristics are improved. Particularly, the characteristics (I-L characteristics) under a high temperature of 50° C. or more are improved.

(b) It is known that, when a desired strain is formed by combining crystals having different lattice constants, crystal defects are generated when a numerical value obtained by multiplying the magnitude of the strain by a thickness of the crystal film exceeds a critical strain. According to the present invention, in the p-type first clad layer having a thickness of 2.0 μm, the thickness of the negative strain layer is 5 to 30 nm, the thickness of each of the positive strain layers respectively provided on both surfaces of the negative strain layer is 5 to 30 nm, and the total film thickness of three of them is 15 to 90 nm in whole, which is less than 100 nm. As a result, in the present invention, the semiconductor laser device can be manufactured without generating crystal defects.

According to the means of above described (2), in the semiconductor laser device, the plurality of negative strain layers and positive strain layers are alternately and periodically provided on the p-type first clad layer. As is explained in the part of the effects of the above means (1), the barrier height is further increased by the negative strain layer and the positive strain layers on the both surface sides thereof, and so more energy is required for causing overflow of the electrons. The barrier further makes occurrence of overflow of the electrons more difficult since the plurality of negative strain layers and positive strain layers are alternately and periodically provided. As a result, temperature characteristics are improved.

### BRIEF DESCRIPTIONS OF THE DRAWINGS

FIG. 1 is a schematic perspective view of a semiconductor laser device of a first embodiment of the present invention;

FIG. 2A is a cross sectional view of FIG. 1 taken along the line A-A;

FIG. 2B is a cross sectional view of FIG. 1 taken along the line B-B;

FIG. 2C is a cross sectional view of FIG. 1 taken along the line C-C;

FIG. 3 is an enlarged cross sectional view of a mesa part of the semiconductor laser device;

FIG. 4 is a schematic diagram showing a band structure of the semiconductor laser device;

FIG. 5 is a graph showing correlation between a strain and In composition in cases where the Al mixed crystal ratio is 0.6 and 0.7;

FIG. 6 is a graph showing correlation between the strain and energy gaps in cases where the Al mixed crystal ratio is 0.6 and 0.7;

FIG. 7 is a table showing calculation results of the strain and compositions when the Al mixed crystal ratio is 0.60;

FIG. 8 is a table showing calculation results of the strain and compositions when the Al mixed crystal ratio is 0.70;

FIG. 9 is a cross sectional view showing a part of a semiconductor wafer formed of a plurality of crystal layers sequentially grown on a main surface of a GaAs substrate in manufacturing of the semiconductor laser device of the first embodiment of the present invention;

FIG. 10 is a schematic plan view of the semiconductor wafer after crystal growth and mesa etching in manufacturing of the semiconductor laser device of the first embodiment;

FIG. 11 is an enlarged cross sectional view of the mesa part taken along the line D-D of FIG. 10;

FIG. 12 is an enlarged cross sectional view showing crystal layers shown in FIG. 11;

FIG. 13 is an enlarged cross sectional view showing the mesa part in the semiconductor wafer having an insulating film is formed on the entire area of a main surface side thereof;

FIG. 14 is an enlarged cross sectional view in which the insulating film is selectively removed so as to expose an uppermost crystal layer in the mesa part;

FIG. 15 is a cross sectional view of a product formation part in which electrodes of a predetermined pattern are formed on the main surface of the semiconductor wafer;

FIG. 16 is a cross sectional view of the product formation part in which an electrode of a predetermined pattern is formed on the back surface of the semiconductor wafer;

FIG. 17 is a schematic view showing a band structure of a semiconductor laser device of a second embodiment of the present invention;

FIG. 18 is a schematic cross sectional view showing a part of a semiconductor laser device studied prior to the present invention; and

FIG. 19 is a schematic diagram showing a band structure of the semiconductor laser device studied prior to the present invention.

### DESCRIPTIONS OF THE PREFERRED EMBODIMENTS

Hereinafter, embodiments of the present invention will be described in detail with reference to the accompanying drawings. Note that, components having the same function are denoted by the same reference symbols throughout the drawings for describing the embodiment, and the repetitive descriptions thereof will be omitted.1

### First Embodiment

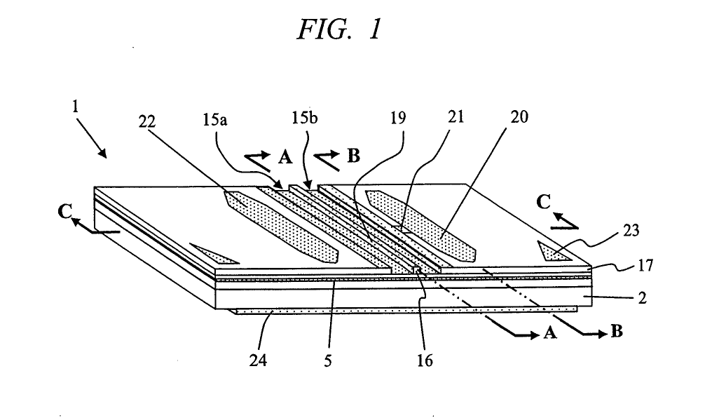

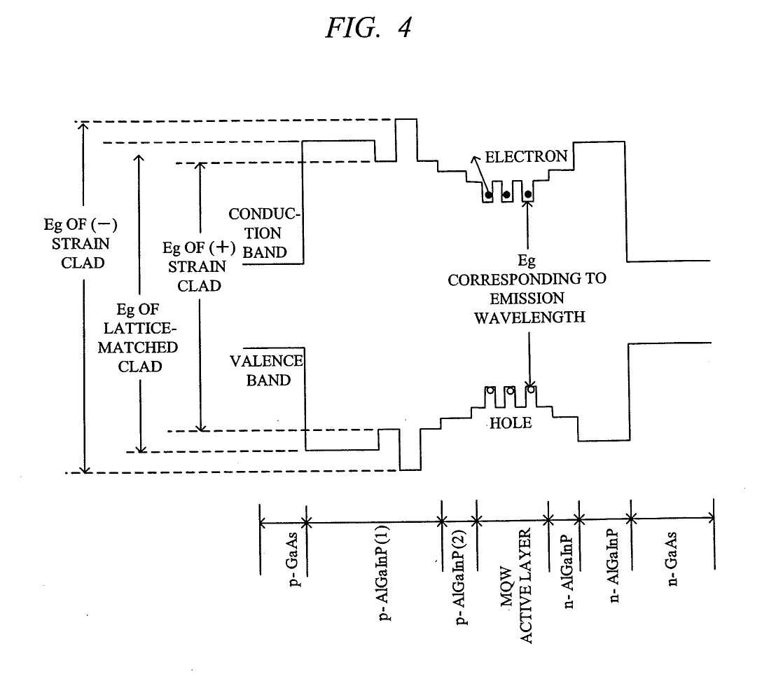

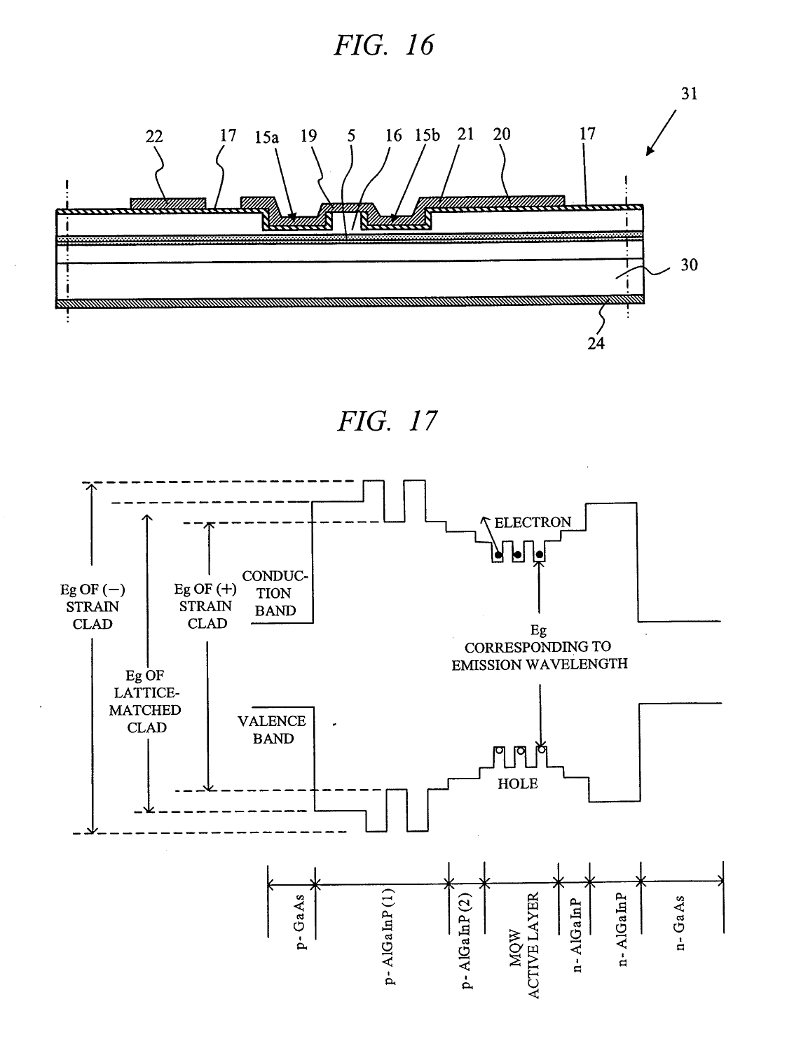

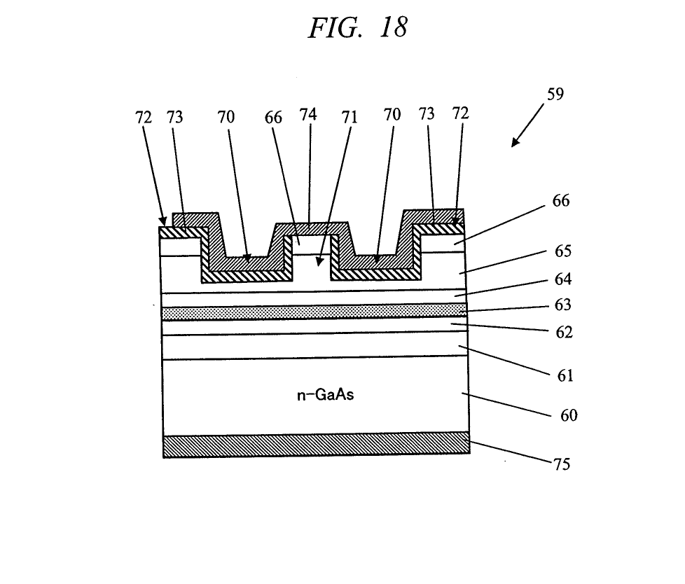

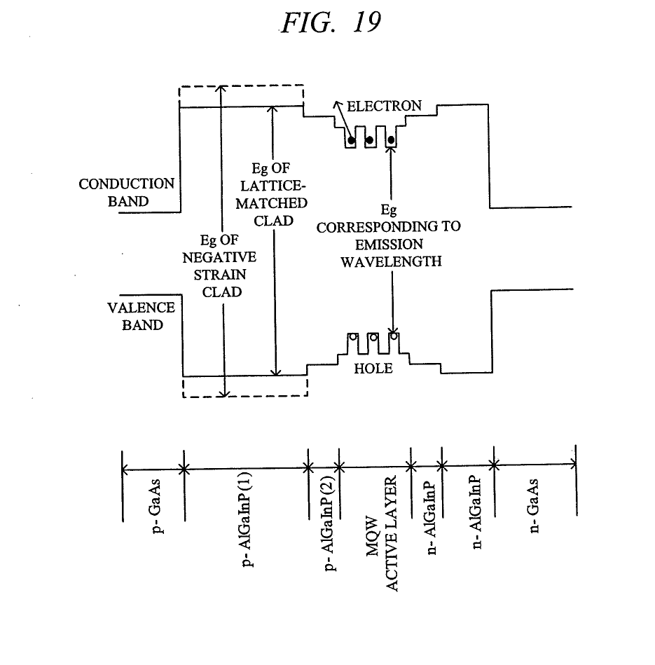

FIG. 1 to FIG. 16 are drawings relating to a semiconductor laser device, which is a first embodiment of the present invention and a method of manufacturing thereof. FIG. 1 to FIG. 3 are drawings relating to a structure of the semiconductor laser device, FIG. 4 to FIG. 8 are drawings relating to strain, and FIG. 9 to FIG. 16 are drawing relating to a manufacturing method of the semiconductor laser device.

In the first embodiment, an example where the present invention is applied to manufacturing of a semiconductor laser device (red semiconductor laser) of 0.6 μm band (oscillation wavelength of 630 to 640 nm) will be described.

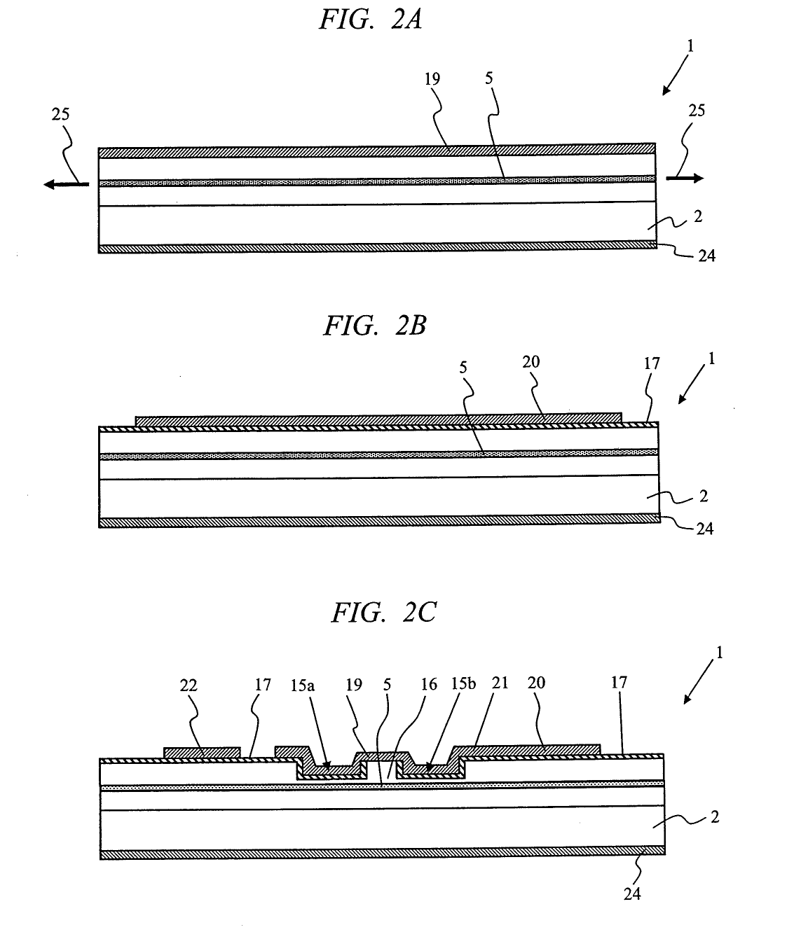

A semiconductor laser device 1 of the first embodiment has a structure shown in FIG. 1 and FIGS. 2A to 2C. FIG. 1 is a schematic perspective view showing external appearance of the semiconductor laser device 1, and FIGS. 2A to 2C are cross sectional views taken along the line A-A, the line B-B, and the line C-C, respectively.

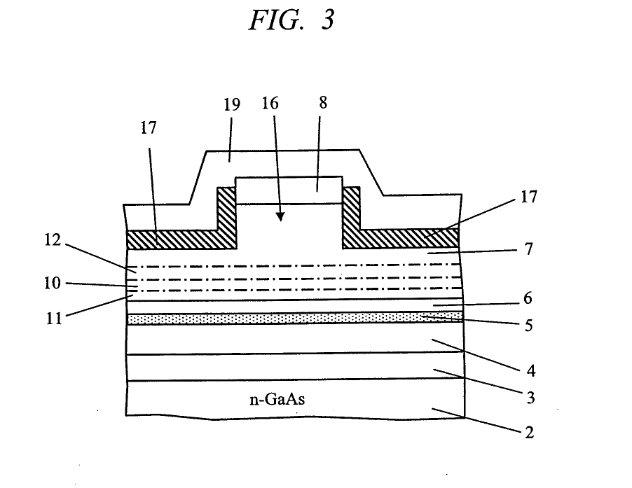

The semiconductor laser device (semiconductor laser chip) 1 is manufactured based on a semiconductor substrate 2 having a thickness of about 100 μm as shown in FIG. 1 and FIGS. 2A to 2C. The semiconductor substrate 2 is, for example, a GaAs substrate 2 of a first conductive type (n type). On a main surface (upper surface in FIG. 1 and FIGS. 2A to 2C) of the n-GaAs substrate 2, as shown in FIG. 3, an n-type buffer layer 3, an n-type clad layer 4, an active layer 5, a second clad layer 6 of a first conductive type (p type), a p-type first clad layer 7, and a p-type contact layer 8 are formed. A multilayer growth layer from the buffer layer 3 to the contact layer 8 is formed by, for example, metal organic vapor deposition (MOCVD).

The n-type buffer layer 3 is composed of (Al_{0.60}Ga_{0.40})_{0.53}In_{0.47}P having a thickness of 1.0 μm. The n-type clad layer 4 is composed of (Al_{0.60}Ga_{0.40})_{0.53}In_{0.47}P having a thickness of 50 nm. The active layer 5 has a multi-quantum well structure formed of barrier layers each of which composed of (Al_{0.60}Ga_{0.40})_{0.53}In_{0.47}P having a thickness of 6 nm and well layers composed of In_{0.38}Ga_{0.62}P having a thickness of 12 nm alternately stacked. In the present embodiment, the number of the barrier layers is 3, and the number of the well layers is 2. The second clad layer 6 is composed of (Al_{0.60}Ga_{0.40})_{0.53}In_{0.47}P having a thickness of 50 nm. The first clad layer 7 is composed of (Al_{0.70}Ga_{0.30})_{0.53}In_{0.47}P having a thickness of 2.0 μm. The contact layer 8 is composed of GaAs having a thickness of 0.2 μm.

Further, as shown in FIG. 3, a negative strain layer 10 is provided as an intermediate layer of the first clad layer 7, and positive strain layers 11 and 12 are provided on both surfaces of the negative strain layer 10 as well. The positive strain layer 11 is stacked on the second clad layer 6. The negative strain layer 10 can be formed by selecting a predetermined amount as the component amount of In of the intermediate layer of (Al_{0.70}Ga_{0.30})_{0.53}In_{0.47}P constituting the first clad layer 7. The positive strain layers 11 and 12 can be formed by selecting a predetermined amount as the component amount of In of regions having predetermined thicknesses on the both surfaces of the negative strain layer 10 of (Al_{0.70}Ga_{0.30})_{0.53}In_{0.47} constituting the first clad layer 7. For example, the strain of the negative strain layer 10 is −0.5 to −1.5%, and the thickness thereof is 5 to 30 nm. The strain of the positive strain layers 11 and 12 is +0.5 to +1.5%, and the thickness thereof is 5 to 30 nm. FIG. 4 is a band diagram of the semiconductor laser device 1. The energy bandgap of the negative strain layer 10 is larger than the energy bandgap of the first clad layer 7 which is lattice-matched to the Gabs substrate 2, and the energy bandgap of the positive strain layers 11 and 12 are smaller than the energy bandgap of the first clad layer 7 lattice-matched to the GaAs substrate 2. Thus, electrons do not readily overflow.

Note that, in FIG. 1 and FIGS. 2A to 2C, the multilayer growth layer is indicated by the active layer 5 denoted by the reference numeral, and the other layers are partially omitted with the reference numerals thereof also omitted. Some of the drawings of the manufacturing method are provided in a similar manner.

Meanwhile, on an upper surface (main surface side of the GaAs substrate 2) of the multilayer growth layer, two grooves 15a and 15b are provided in parallel as shown in FIG. 1 and FIG. 2C. As shown in FIG. 3, the grooves 15a and 15b have a structure which reaches an intermediate depth of the first clad layer 7. The part sandwiched by the pair of grooves 15a and 15b is a mesa (projection) 16 formed of p-type AlGaInP. The width of the mesa 16 is about 2 μm, and the width of each of the grooves 15a and 15b is about 10 μm.

On the upper surface of the semiconductor laser device 1, an insulating film 17 is provided. As shown in FIG. 2C, the insulating film 17 covers side surfaces of the mesa 16, the grooves 15a and 15b, and the contact layer positioned outside the grooves 15a and 15b. Therefore, as shown in FIG. 2C and FIG. 3, the upper surface side of the mesa 16 is exposed from the insulating film 17.

Moreover, on the insulating film 17, a conductor layer having a predetermined pattern is provided. The conductor layer is shown by dotted regions in FIG. 1. As shown in FIG. 1, a part of the conductor layer is stacked with the upper surface of the mesa 16 and forms a first electrode (p electrode) 19, which is in a state electrically connected to the mesa 16. The first electrode (p electrode) 19 extends to above outside edges of the pair of grooves 15a and 15b. The conductor layer having a wide area is also provided on a flat part (field part) outside the groove 15b. This conductor layer having the wide area constitutes a bonding pad 20 which connects a wire. The bonding pad 20 and the first electrode 19 are electrically connected to each other by a thin coupling part 21. Also, an independent fixing conductor part 22 is formed on the insulating layer 17 in the left side outside the groove 15a. The fixing conductor part 22 and the first electrode 19 are used as a fixing conductor layer when the semiconductor laser device 1 is fixed to a substrate of, for example, a heat sink by junction-down (state in which pn junction is in the lower side).

In the vicinities of both ends of the semiconductor laser device 1, triangular marks 23 are provided. The marks 23 are also formed of the conductor layer. The marks 23 are used as indicators when a semiconductor wafer is cleaved to manufacture the semiconductor laser device 1 in the manufacturing of the semiconductor laser device 1.

Further, a second electrode (n electrode) 24 is formed on a back surface, which is the opposite surface of the main surface of the semiconductor substrate 2.

A long and thin region formed by a part of the clad layer 4, a part of the active layer 5, and a part of the second clad layer corresponding to the mesa 16 forms a resonator. Therefore, when a predetermined voltage is applied between the p electrode 19 and the n electrode 24, laser light 25 is emitted from both end faces (emitting faces) of the resonator as shown in FIG. 2A. Although it is not illustrated, generally, films having predetermined refraction indexes are formed respectively on both of the emitting faces so that the output power of the emitted laser light is different. The side having large output power is used as a front emitting face, and the side having small output power is used as a rear emitting face which is a face for extracting the light for monitoring laser light intensity.

Herein, the negative strain layer 10 and the positive strain layers 11 and 12 will be further described. The negative strain layer 10 has a thickness of 5 to 30 nm, and its strain is arranged to be −0.5 to −1.5% so that the semiconductor laser device 1 has the band structure shown in FIG. 4. Also, each of the positive strain layers 11 and 12 has a thickness of 5 to 30 nm, and its strain is arranged to be +0.5 to +1.5%.

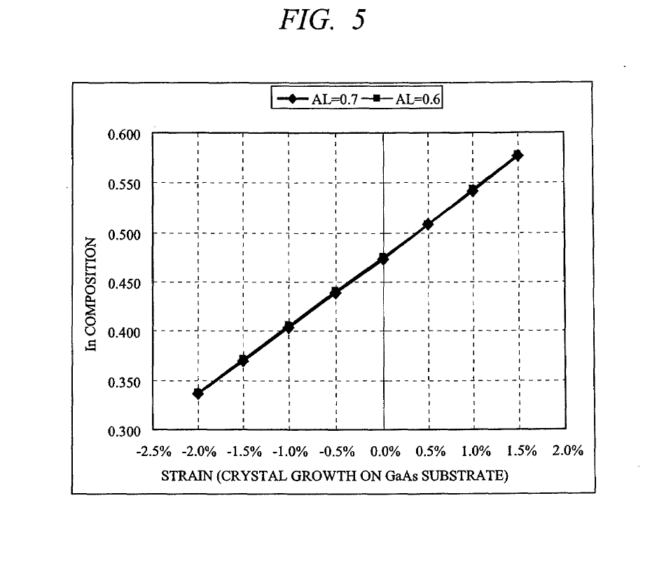

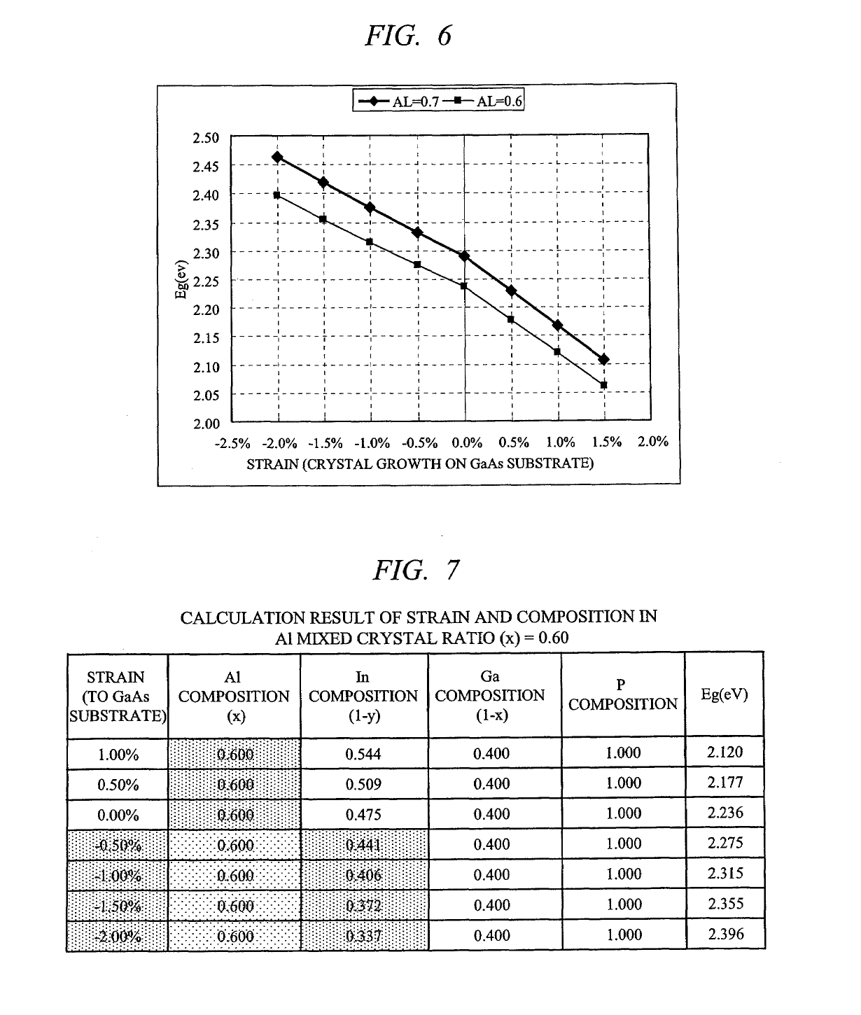

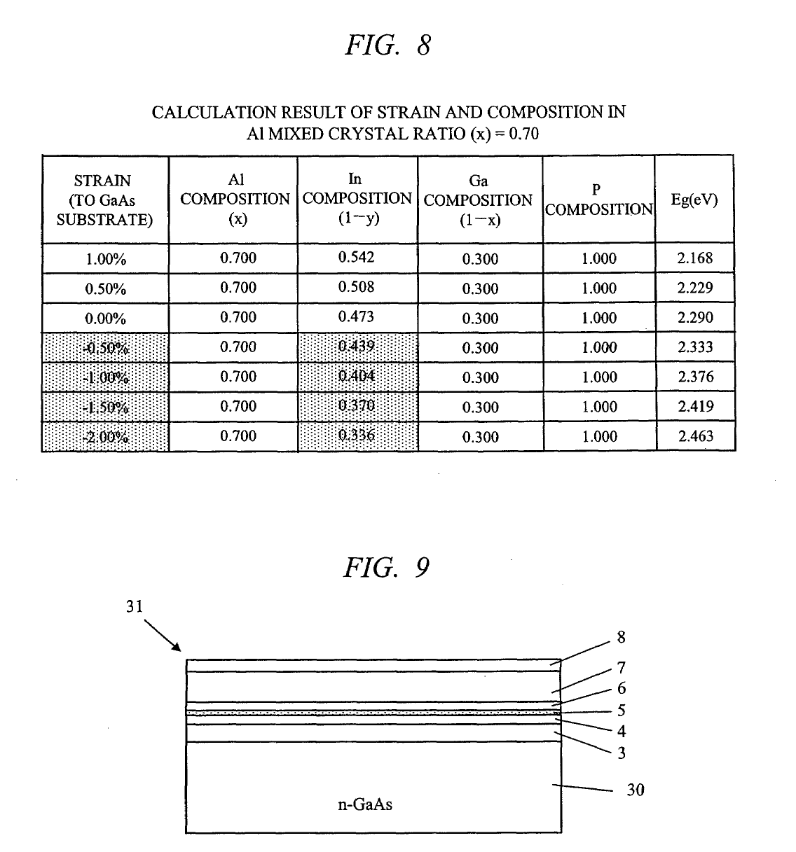

FIG. 5 is a graph showing correlation between the strain and In composition in the cases for Al mixed crystal ratios of 0.6 and 0.7. FIG. 6 is a graph showing correlation between the strain and energy gaps in the cases for the Al mixed crystal ratios of 0.6 and 0.7. FIG. 7 is a table showing calculation results of the strain and compositions when the Al mixed crystal ratio is 0.60, and FIG. 8 is a table showing calculation results of the strain and compositions when the Al mixed crystal ratio is 0.70.

In order to make the strain of the negative strain layer 10 to be −0.5 to −1.5%, as it can be understood from the graphs of FIG. 5 and FIG. 8, when the composition of In (mixed crystal ratio) in the (Al_{0.70}Ga_{0.30})_{0.53}In_{0.47}P layer is in the range from about 0.439 to about 0.37, the energy bandgap of the negative strain layer 10 can be made to be about 2.258 eV to about 2.351 eV as it can be understood from the graph of FIG. 6. Note that, in the graph of FIG. 5, the graph showing the correlation between the strain and In composition when the composition of Al is 0.7 and the graph showing the correlation between the strain and In composition when the composition of Al is 0.6 are roughly same graphs.

Also, in order to make the strain of the positive strain layers 11 and 12 to be +0.5 to +1.5%, as it can be understood from the graphs of FIG. 5 and FIG. 8, when the composition of In in the (Al_{0.70}Ga_{0.30})_{0.53}In_{0.47}P layer is in the range from about 0.508 to about 0.576, the energy bandgaps of the positive strain layers 11 and 12 can be made to be about 2.175 eV to about 2.062 as it can be understood from the graph of FIG. 6.

Next, the manufacturing method of the semiconductor laser device 1 will be described with reference to FIG. 9 to FIG. 16. In manufacturing of the semiconductor laser device 1, a semiconductor substrate 30 is prepared. The multilayer growth layer is formed on a main surface of the semiconductor substrate 30, and the substrate is subjected to respective processing processes and, in a last stage of manufacturing, subjected to division and cleavage. A plurality of the semiconductor laser devices 1 is manufactured by the division and cleavage. Such semiconductor substrate 30 is generally referred to as a semiconductor wafer 31. The semiconductor wafer 31 is the semiconductor substrate 30 itself at the beginning, but has a structure having the multilayer growth layer and the like at the point after it has undergone respective manufacturing processes. However, it is called as the semiconductor wafer 31 until division and cleavage are performed. In the description hereinafter, a single semiconductor laser device part of the semiconductor wafer 31 will be described.

First, the semiconductor wafer 31 is prepared. The semiconductor wafer 31 is composed of the n-conductive-type (first conductive type) GaAs substrate (semiconductor substrate) 30 having a thickness of several hundreds of am. The n-type GaAs substrate 30 uses Si as an impurity, and the impurity concentration is about 2.0×10¹⁸ cm⁻³. The main surface of the n-type GaAs substrate 30 is the crystal face of (100).

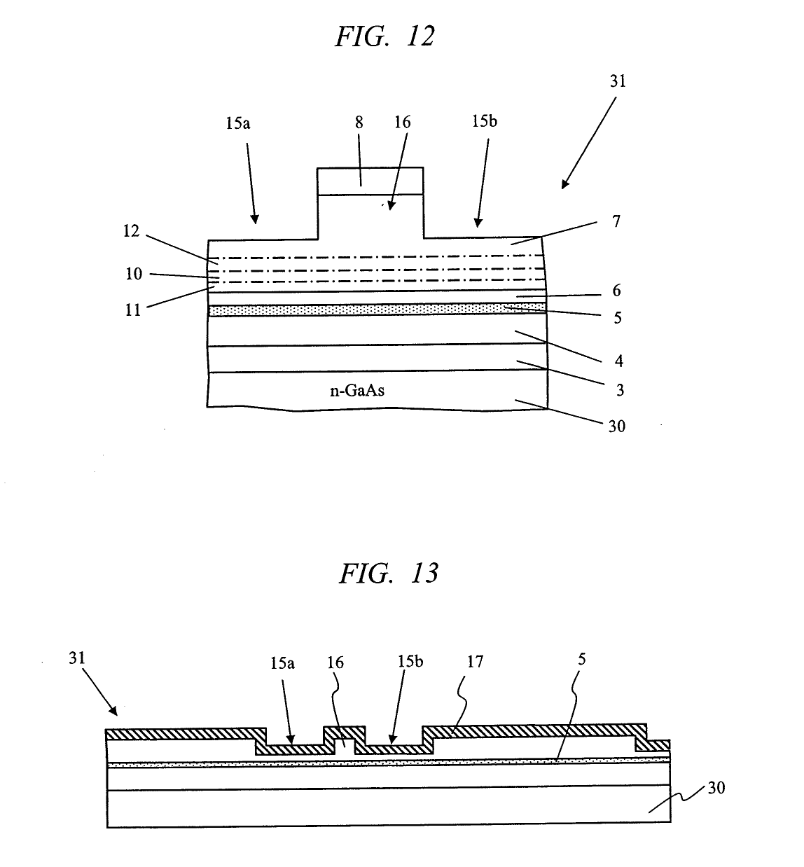

Next, semiconductor layers are sequentially formed on the main surface (upper surface) side of the wafer 31 by MOCVD (Metalorganic Chemical Vapor Deposition) method or MBE (Molecular Beam Epitaxy) method, thereby forming the multilayer growth layer. These semiconductor layers are, as shown in FIG. 9, the above described buffer layer 3, the clad layer 4, the active layer 5, the second clad layer 6, the first clad layer 7, and the contact layer 8. In addition, as shown in FIG. 12, the negative strain layer 10 and the positive strain layers 11 and 12 are also formed in the first clad layer 7. The formation of the negative strain layer 10 and the positive strain layers 11 and 12 is performed by controlling the composition of In in the stage of formation of the first clad layer 7 composed of p-type (Al_{0.70}Ga_{0.30})_{0.53}In_{0.47}P. More specifically, after the second clad layer 6 composed of p-type (Al_{0.60}Ga_{0.40})_{0.53}In_{0.47}P is formed, when the first clad layer 7 composed of p-type (Al_{0.70}Ga_{0.30})_{0.53}In_{0.47}P is to be formed, the composition of In (mixed crystal ratio) is controlled to a range from about 0.439 to about 0.37 so as to form the positive strain layer 11 having a thickness of 5 to 30 nm subsequent to the formation of the second clad layer 6. Then, the composition (crystal mixed ratio) of In is controlled to a range from about 0.508 to about 0.576 so as to form the negative strain layer 10 having a thickness of 5 to 30 nm. Then, the composition (mixed crystal ratio) of In is controlled to a range from about 0.439 to about 0.37 so as to form the positive strain layer 12 having a thickness of 5 to 30 nm. In FIG. 9, the negative stain layer 10 and the positive strain layers 11 and 12 are omitted.

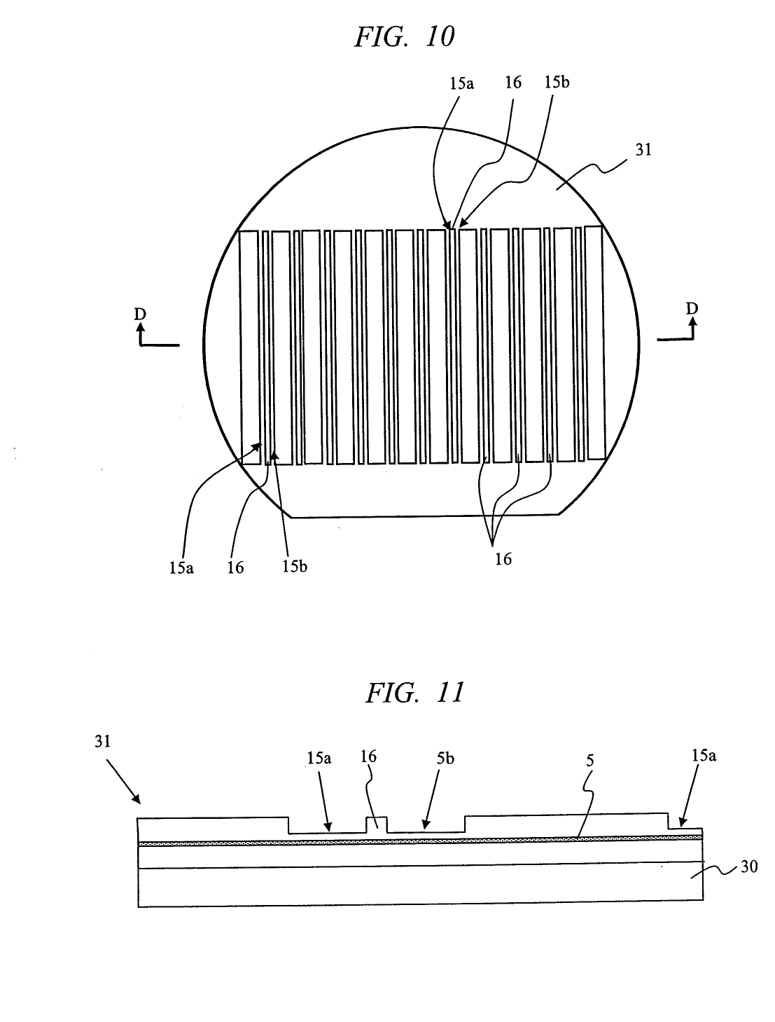

Next, as shown in FIG. 10 and FIG. 11, two lines of grooves 15a and 15b are formed with a predetermined interval by common photolithography techniques and etching techniques, thereby forming the mesa 16 sandwiched between the grooves 15a and 15b. FIG. 11 is a schematic enlarged cross sectional view taken along the line D-D in FIG. 10, and FIG. 12 is an enlarged cross sectional view of a part including the mesa 16 of FIG. 11.

The bottoms of the grooves 15a and 15b are close to the active layer 5 and extend to an intermediate depth of the first clad layer 7 as shown in FIG. 12. The thickness of the first clad layer 7 at the bottom surfaces of the grooves 15a and 15b is, for example, about 300 nm. For example, the width of the mesa 16 is 2 μm, and the width of each of the grooves 15a and 15b is 10 μm.

Next, as shown in FIG. 13, the insulating film 17 composed of SiO₂ is formed on the entire area of the main surface side of the semiconductor wafer 31. The thickness of the insulating film 17 is 0.1 to 0.3 μm.

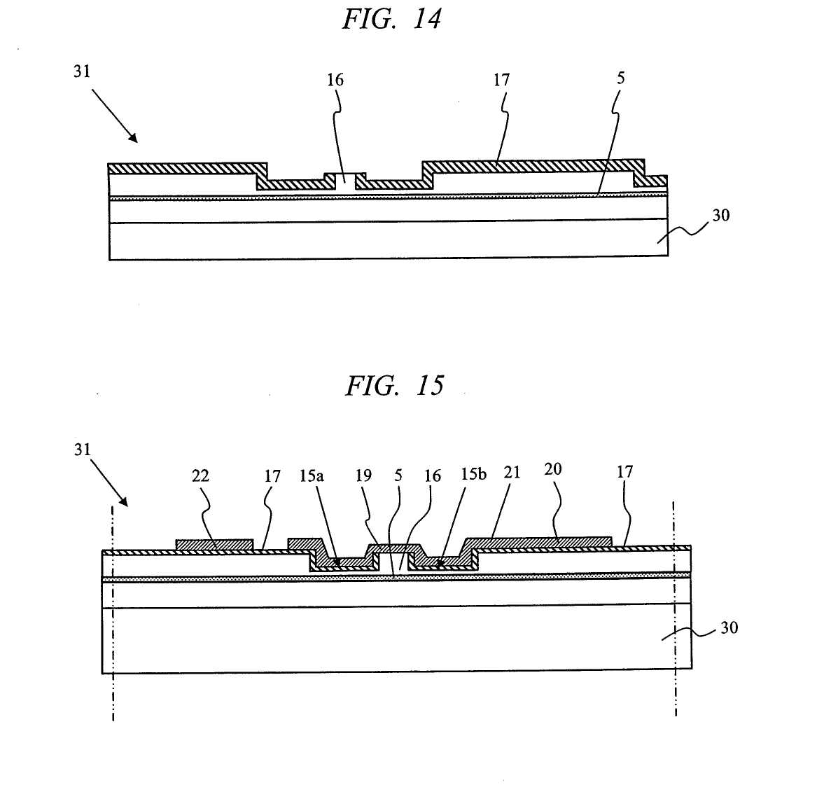

Next, after a photoresist film is formed on the entire area of the main surface side of the semiconductor wafer 31, the photo mask above the mesa 16 is removed. Then, the insulating film 17 is etched by using the photoresist film as an etching mask. As a result, as shown in FIG. 14, the mesa 16 is exposed from the insulating film 17.

Next, a conductor layer is formed on the entire area of the main surface of the semiconductor wafer 31, and the conductor layer is patterned by common photo lithography techniques and etching techniques. As a result of this patterning, as shown in FIG. 15, the above described first electrode (p electrode) 19, the bonding pad 20, the coupling part 21, the fixing conductor part 22, and the marks 23 (see FIG. 1) are formed. The first electrode (p electrode) 19 is thus electrically connected with the mesa 16.

Next, although it is not illustrated, the back surface, which is the opposite surface of the main surface of the semiconductor wafer 31, is removed by a predetermined thickness so as to make the semiconductor wafer 31 have a thickness of about 100 μm, and the second electrode (n electrode) 24 is formed on the entire area of the back surface of the semiconductor wafer 31, in other words, the back surface of the n-type GaAs substrate 30.

Next, the semiconductor wafer 31 is divided vertically and horizontally, thereby manufacturing the plurality of semiconductor laser devices 1. In this division, for example, the part in the middle of the mesa 16 and the mesa 16 is cut, for example, by a dicing blade to form strips. And, the strips are then divided by cleavage, thereby manufacturing the semiconductor laser devices 1.

According to the first embodiment, the following effects are provided.

(1) The negative strain layer 10 is provided in the intermediate layer of the p-type first clad layer ((Al_{0.70}Ga_{0.30})_{0.53}In_{0.47}P) 7, and the positive strain layers 11 and 12 are provided on the both surfaces thereof. The strain of the negative strain layer 10 is −0.5 to −1.5%, and the thickness thereof is 5 to 30 nm. The strain of the positive strain layers 11 and 12 is +0.5 to +1.5%, and the thickness thereof is 5 to 30 nm.

In the energy bandgap of the p-type first clad layer 7, the strain is ±0% since the p-type first clad layer 7 is lattice-matched with the GaAs substrate 2. On the other hand, the strain is −0.5 to −1.5% in the part in which the negative strain layer 10 is formed, and the strain is +0.5 to +1.5% in the positive strain layers 11 and 12 provided in the both surface sides of the negative strain layer 10. Therefore, the energy gap is increased and the electrons in the active layer 5 do not readily overflow, and thus characteristics (I-L characteristics) are improved and temperature characteristics are improved. Particularly, the characteristics (I-L characteristics) are good under a high temperature of 50° C. or more.

(2) In the case in which desired strain is formed by combining crystals having different lattice constants, it is known that crystal defects are generated when the numerical value obtained by multiplying the magnitude of the strain by the film thickness of the crystal exceeds a critical value (critical strain). In the embodiment, in the p-type first clad layer 7 having a thickness of 2.0 μm, the thickness of the negative strain layer 10 is 5 to 30 nm, the thickness of each of the positive strain layers 11 and 12 provided on both surfaces of the negative strain layer 10 is 5 to 30 nm, and the thickness as a whole is 15 to 90 nm, which is less than 100 nm, even when the thicknesses of the three films are added. As a result, in the present embodiment, the semiconductor laser device 1 can be manufactured without generating crystal defects.

### Second Embodiment

Although it is not illustrated, a semiconductor laser device of the second embodiment has a structure in which a plurality of negative strain layers 10 and the positive strain layers 11 and 12 are alternately and periodically provided in the first clad layer 7 in the semiconductor laser device 1 of the first embodiment. FIG. 17 is a diagram showing a band structure of the semiconductor laser device which is the second embodiment. The band structure of FIG. 17 is a structure in which two negative strain layers are provided in the band structure of FIG. 4 of the semiconductor laser device 1 of the first embodiment. More specifically, on the second clad layer 6, the positive strain layer 11, the negative strain layer 10, the positive strain layer 12, and the negative strain layer 10 are stacked. The structures of the negative strain layer 10 and the positive strain layers 11 and 12 are same as the structures of the semiconductor laser device 1 of the first embodiment.

Such semiconductor laser device of the second embodiment is formed upon formation of the first clad layer 7 in the formation stage of the multilayer growth layer by sequentially controlling the composition of In in formation of the positive strain layer, the negative strain layer, the positive strain layer, the negative strain layer, and the first clad layer. In the second embodiment, the number of the negative strain layers is two. However, the number may be larger.

As already described in the description of effect of the semiconductor laser device of the first embodiment, the barrier height is further increased by the negative strain layer and the positive strain layer on both sides thereof, and thus overflow of electrons requires further larger energy. Moreover, since the plurality of negative strain layers and positive strain layers are alternately and periodically provided, overflow of the electrons is more difficult to occur with the barrier height. As a result, temperature characteristics are improved.

In the foregoing, the invention made by the inventor of the present invention has been concretely described based on the embodiments. However, it is needless to say that the present invention is not limited to the foregoing embodiments and various modifications and alterations can be made within the scope of the present invention. In the embodiments, the positive strain layers 11 and 12 are provided on both surface sides of the negative strain layer 10. However, even when the positive strain layer is formed in either one surface side of the negative strain layer 10, overflow of the electrons can be suppressed and the temperature characteristics of the semiconductor laser device 1 can be improved because the barrier height between the negative strain layer 10 and the positive strain layer is large.

What is claimed is:

1. A semiconductor laser device comprising:
a semiconductor substrate of a first conductive type;
a clad layer of the first conductive type formed on a main surface of the semiconductor substrate;
an active layer formed on an upper surface of the clad layer;
a second clad layer of a second conductive type formed on an upper surface of the active layer;
a first clad layer of the second conductive type formed on an upper surface of the second clad layer;
a contact layer of the second conductive type formed on an upper surface of the first clad layer;
a second electrode which is stacked on the contact layer and provided so as to correspond to an end to another end of a long and thin resonator formed of: the clad layer of the first conductive type; the active layer; the second clad layer; and the first clad layer, and injects a current to the active layer part of the resonator; and
a first electrode stacked on a back surface which is an opposite surface of the main surface of the semiconductor substrate,
wherein the clad layer of the first conductive type and the first clad layer are arranged to be lattice-matched to the semiconductor substrate;
a negative strain layer is provided in an intermediate layer of the first clad layer; and
a positive strain layer is provided on one or both surfaces of the negative strain layer.

2. The semiconductor laser device according to claim 1, further comprising:
two grooves provided from a surface of the contact layer so as to reach an intermediate depth of the first clad layer;
a mesa composed of the first clad layer and the contact layer formed being sandwiched between the two grooves; and
an insulating film covering the grooves and the contact layer except for an upper surface of the mesa,
wherein the second electrode is electrically connected to the upper surface of the mesa, and
a lower part of the mesa constitutes the resonator.

3. The semiconductor laser device according to claim 1,
wherein the semiconductor substrate is composed of GaAs;
the clad layer of the first conductive type is composed of (Al_{0.60}Ga_{0.40})_{0.53}In_{0.47}P;
the active layer has a multi-quantum well structure in which a barrier layer composed of (Al_{0.60}Ga_{0.40})_{0.53}In_{0.47}P and a well layer composed of In_{0.38}Ga_{0.62}P are alternately stacked;
the second clad layer is composed of (Al_{0.60}Ga_{0.40})_{0.53}In_{0.47}P;
the first clad layer is composed of (Al_{0.70}Ga_{0.30})_{0.53}In_{0.47}P;
the contact layer is composed of GaAs;
the negative strain layer is formed by selecting a predetermined amount as a component amount of In in the intermediate layer of (Al_{0.70}Ga_{0.30})_{0.53}In_{0.47}P composing the first clad layer; and
the positive strain layer is formed by selecting a predetermined amount as a component amount of In in a region having a predetermined thickness in one or both surfaces of the intermediate layer of (Al_{0.70}Ga_{0.30})_{0.53}In_{0.47}P composing the first clad layer.

4. The semiconductor laser device according to claim 3,
wherein a thickness of the clad layer of the first conductive type is 50 nm;
the active layer having the multi-quantum well structure is formed of three layers of the barrier layer each of which having a thickness of 6 nm and two layers of the well layer each of which having a thickness of 12 nm;
the second clad layer has a thickness of 50 nm;
the first clad layer has a thickness of 2.0 μm; and
the contact layer has a thickness of 0.2 μm.

5. The semiconductor laser device according to claim 3,
wherein the negative strain layer has a strain of −0.5 to −1.5% and a thickness of 5 to 30 nm, and the positive strain layer has a strain of +0.5 to +1.5% and a thickness of 5 to 30 nm.

6. The semiconductor laser device according to claim 1,
wherein a plurality of the negative strain layers and the positive strain layers are alternately and periodically provided.

7. The semiconductor laser device according to claim 1,
wherein a buffer layer of the first conductive type is provided between the semiconductor substrate and the clad layer of the first conductive type.

8. A manufacturing method of a semiconductor laser device including:
(a) a step of preparing a semiconductor substrate of a first conductive type;
(b) a step of sequentially forming and stacking: a clad layer of the first conductive type; an active layer; a second clad layer of a second conductive type; a first clad layer of the second conductive type; and a contact layer of the second conductive type on a main surface of the semiconductor substrate;
(c) a step of forming a plurality of pairs of grooves reaching an intermediate depth of the first clad layer from a surface of the contact layer at a predetermined interval so that a plurality of projecting mesas each of which sandwiched between the pair of grooves above the active layer are formed, and forming a resonator below the mesa;
(d) a step of removing an upper surface of the mesa and forming an insulating film covering an upper surface side of the semiconductor substrate;
(e) a step of forming a second electrode selectively formed on the insulating film, a part thereof is stacked on the mesa;
(f) a step of forming a first electrode on a back surface which is an opposite surface of the main surface of the semiconductor substrate; and
(g) a step of dividing the semiconductor substrate and the layers thereon from a part between the mesa and mesa and cleaving the substrate and the layers in a direction orthogonal to the mesa at a predetermined interval so as to form a plurality of rectangular semiconductor laser devices,
wherein, in the step (b),
the clad layer of the first conductive type and the first clad layer are formed so as to be lattice-matched to the semiconductor substrate,
a negative strain layer is provided in an intermediate layer of the first clad layer, and
a positive strain layer is provided on one or both surfaces of the negative strain layer.

9. The manufacturing method of a semiconductor laser device according to claim 8,
wherein a GaAs substrate is prepared as the semiconductor substrate in the step (a), and
in the step (b),
the clad layer of the first conductive type is formed of (Al_{0.60}Ga_{0.40})_{0.53}In_{0.47}P;
the active layer is formed to have a multi-quantum well structure in which a barrier layer composed of (Al_{0.60}Ga_{0.40})_{0.53}In_{0.47}P and a well layer composed of In_{0.38}Ga_{0.62}P are alternately stacked;
the second clad layer is formed of (Al_{0.60}Ga_{0.40})_{0.53}In_{0.47}P;
the first clad layer is formed of (Al_{0.70}Ga_{0.30})_{0.53}In_{0.47}P;
the contact layer is formed of GaAs;
the negative strain layer is formed by selecting a predetermined amount as a component amount of In in the intermediate layer of (Al_{0.70}Ga_{0.30})_{0.53}In_{0.47}P composing the first clad layer; and
the positive strain layer is formed by selecting a predetermined amount as a component amount of In in a region having a predetermined thickness in one or both surfaces of the intermediate layer of (Al_{0.70}Ga_{0.30})_{0.53}In_{0.47}P composing the first clad layer.

10. The manufacturing method of a semiconductor laser device according to claim 9,
wherein the clad layer of the first conductive type is formed to have a thickness of 50 nm;
the active layer having the multi-quantum well structure is formed by three of the barrier layers each of which having a thickness of 6 nm and two of the well layers each of which having a thickness of 12 nm;
the second clad layer is formed to have a thickness of 50 nm;
the first clad layer is formed to have a thickness of 2.0 μm; and
the contact layer has a thickness of 0.2 μm.

11. The manufacturing method of a semiconductor laser device according to claim 9,
wherein, in the step (b),
the negative strain layer having a strain of −0.5 to −1.5% and a thickness of 5 to 30 nm is formed, and
the positive strain layer having a strain of +0.5 to +1.5% and a thickness of 5 to 30 nm is formed.

12. The manufacturing method of a semiconductor laser device according to claim 8,
wherein, in the step (b),
a plurality of the negative strain layers and positive strain layers are alternately and periodically and formed.

13. The manufacturing method of a semiconductor laser device according to claim 8,
wherein, in the step (b),
after a buffer layer of the first conductive type is formed on the main surface of the semiconductor substrate, the clad layer is formed on the buffer layer.
